(19) United States
(12) Patent Application Publication
(10) Pub. No.: US 2014/0242744 A1
(43) Pub. Date: Aug. 28, 2014

(54) SUBSTRATE AND SUPERSTRATE DESIGN AND PROCESS FOR NANO-IMPRINTING LITHOGRAPHY OF LIGHT AND CARRIER COLLECTION MANAGEMENT DEVICES

(71) Applicants: Stephen J. Fonash, State College, PA (US); Wook Jun Nam, State College, PA (US)

(72) Inventors: Stephen J. Fonash, State College, PA (US); Wook Jun Nam, State College, PA (US)

(73) Assignee: SOLARITY, INC., State College, PA (US)

(21) Appl. No.: 14/347,585

(22) PCT Filed: May 7, 2012
(86) PCT No.: PCT/US2012/036732

§ 371 Date: Mar. 26, 2014

Related U.S. Application Data
(60) Provisional application No. 61/539,065, filed on Sep. 26, 2011.

(51) Int. Cl. H01L 31/0232

(52) U.S. Cl. CPC H01L 31/02327
USPC 438/71

(57) ABSTRACT

A process for forming a nano-element structure is provided that includes contacting a template with a material to form the nano-element structure having an array of nano-elements and a base physically connecting the array of nano-elements. The material that is contacted with the template is the nano-element structure material or precursor material from which the array of nano-elements is formed. The nano-element structure is then removed from contact with the template. The nano-element structure material or its precursor is brought into contact with the template for the forming of the array of nano-elements by techniques such as nano-imprinting and printing. A final substrate subsequently supports the array of nano-elements so produced. The array of nano-elements is exposed free and at least one layer of a dopant layer, a spacer layer, a light absorber layer, a conductor, or a counter electrode layer, are employed to complete an operative device.

### RELATED APPLICATIONS

This application claims priority benefit of U.S. Provisional Application Ser. No. 61/559065 filed 26 Sep. 2011; the contents of which are hereby incorporated by reference.

### FIELD OF THE INVENTION

The present invention in general relates to a device containing a nano-element structure; to design of such a device, and in particular to the use of nano-imprinting, printing, and substrate transfer processing in a manufacturing approach for producing light and carrier collection management (LCCM) devices. These devices are operative as photo-active devices, for example solar cell photovoltaics, photosynthesis devices, or light detection devices, as well as charge storage devices.

### BACKGROUND OF THE INVENTION

Historically, photovoltaic and light detection devices such as photodetector devices, lithium drifted silicon based detectors, and photo electron effect devices have been formed as planar layers successively constructed to afford a functioning device. Owing to the high optical reflectivity of planar substrates and poor optical path length matching, such devices, particularly photovoltaic devices, have traditionally exhibited low light harvesting efficiencies. In recognition of this limitation, such devices are preferentially etched or otherwise textured to promote internal light reflection within the light harvesting portions of the device. While surface texturing incrementally improves light harvesting efficiency on such devices, the texturing process is far from uniform and inefficient in material usage.

Light sensitive devices are tailored for the part of the electro-magnetic spectrum for which they are designed. For example, solar cell devices are tailored to interact with at least some portion of the photon-rich ultra-violet, visible, and infra-red parts of the solar spectrum. In order for solar cell photovoltaics, photosynthesis devices and light detection devices to reach their respective maximal operational potentials, devices must prove not only light absorbing for the spectrum for which they are designed but also effective in converting photons with minimal losses into electrical carriers and then efficiently extracting such carriers to an electrical circuit. To achieve these objectives, light and carrier collection management (LCCM) devices have been developed that have multi-scale electrode architecture and controlled three dimensional structures that attempt to optimize light absorption, photon conversion to electrical carriers, and carrier collection along with efficient material utilization. For the fabrication of LCCM devices, electron beam (e-beam) lithography has been used for pattern definition of the crucial nano-scale electrode structures. The technique has been ideal for optimizing the nano-structure dimensions (e.g., diameter of electrode nano-element columns, inter-columnar spacing) and nano-element spacing arrangement, since it offers the opportunity to explore many different patterns due to its flexibility. However, the technique is slow and expensive and therefore not suitable for high throughput device production. The incorporation of two-dimensional (2-D) nano-element arrays into thin film solar cell structures has been studied by a number of groups for its light trapping [1-6] because, unlike gratings, their response to light is relatively independent of the polarization of the incident light wave.[7] In addition, conducting nano-element arrays can assist in photocarrier collection.[1] This “collecting nano-element” geometry potentially offers an additional advantage of enhanced photo-carrier collection and can thereby give rise to both effective light and carrier collection management (LCCM) advantages.

These configurations can give enhanced light trapping through effective absorber thickness and plasmonic and photonic effects [5, 6]. The LCCM concept can be used in superstrate (light enters through the substrate) configurations, with the array on the substrate, and in substrate (light enters through the free surface) configurations, also with the array on the substrate. Since substrate cells do not have the array transparency requirement, they have used metallic (e.g., silver) arrays. The use of metallic arrays has attracted great attention since it is argued that this use of metallic arrays offers, in addition to effective absorber thickness and photonic effects, the advantage of light trapping through the plasmonic phenomena of (1) metallic nano-element scattering, (2) metallic nano-element near-field enhancement in the absorber, and (3) structured metallic surface scattering into plasmon polariton and photonic modes [2-4]. Prior modeling has supported the view that this metallic (e.g., Ag) nano-element array substrate design is more effective than the superstrate architectures [3, 6]. The requirement of reliance on metallic element arrays in the prior art has limited the manufacturability and increased costs of such cells.

Thus, there exists a need for a process to form LCCM device nanostructures more efficiently and with a process amenable to mass production. There further exists a need for a continuous operation of nano-imprinting or printing lithography system for modifying a substrate to include producing nano-element structures of a controlled shape, size and inter-element spacing and arrangement.

### SUMMARY OF THE INVENTION

A process for forming a nano-element structure is provided that includes contacting a template with a material to form the nano-element structure having an array of nano-elements and a base physically connecting the array of nano-elements. The material that is contacted with the template is the nano-element structure material or precursor material from which the array of nano-elements is formed. The nano-element structure is then removed from contact with the template. The nano-element structure material or its precursor is brought into contact with the template for the forming of the array of nano-elements by techniques such as nano-imprinting and printing. The process is amenable to being done in continuous processing fashion. A final substrate subsequently supports the array of nano-elements so produced. The array of nano-elements is exposed free and at least one layer of a dopant layer, a spacer layer, a light absorber layer, a conductor, or a counter electrode layer, are employed to complete an operative device.

A photo (i.e., light) active or charge storage device is provided with an array of conductive nano-elements in a two-dimensional (2-D) arrangement disposed on a conducting layer or themselves having a base that serves as the conductive layer. This array and conductive layer form an electrode which gives light trapping and photocarrier collecting capability for photo-responsive devices; e.g., the resulting device can provide light and carrier collection management (LCCM) photovoltaic devices. Photovoltaic structures functioning as solar cell structures, for example, may be used as one sun devices or they may be combined with luminescent solar concentrator films or with micro-optics elements positioned in concert with the array for concentrator devices. The same two possibilities of non-concentrator or concentrator options are available for other light responsive devices.

### BRIEF DESCRIPTION OF THE DRAWINGS

FIG. 1: Cross-sectional field emission scanning electron microscopy (FESEM) image of a Solarity a-Si:H single junction superstrate LCCM device (at a 60 degree tilt).

FIG. 2: Depiction of a transparent conducting nano-element array: (a) 2-D hexagonally arranged unit cells and (b) the cross-section of the two adjacent unit cells showing dimensional parameters and materials used in modeling. These nano-elements may have a variety of shapes including cones and columns.

FIG. 3: The short circuit current density as a function of L for H=350 and 550 nm nano-cone LCCM substrate solar cells. The nano-elements are AZO cones with R=200, R*=150, t=200, and d=100 nm. Adjacent unit cells touch if L=L_{touch} and are truncated if L<L_{touch}. The inset shows the architecture example modeled.

FIG. 4: Normalized total Poynting vector P/P_{incident} plots for (a) the planar control cell and (b) the L=550 nm case of an LCCM nano-cone array substrate cell at the wavelength of 681 nm. The quantity P is the magnitude of the total Poynting vector at a point whereas P_{incident} is the magnitude of the Poynting vector of the incoming wave at that point. Depiction is for the cross-section of a unit cell running in the direction that goes through repeating TCO nano-elements. The circuitous re-directing of the power flow by the use of index of refraction variation and shaping of the LCCM structure is apparent.

FIG. 5: Top (plan) view of one of the hexagonal unit cells of the architecture of this inset of FIG. 3 for the case of L=550 nm.

FIGS. 6A-6E: Schematic of nano-imprinting and processing sequence for embodiment 1.

FIGS. 7A-7C: Schematics of details of the back electrode completion, substrate attachment and separation for FIG. 6.

FIGS. 8A-8E: Schematic of nano-imprinting and processing sequence for embodiment 2. This schematic is carried out to indicate grid formation.

FIGS. 9A-9E: Schematic of the nano-printing and processing sequence for the second approach of embodiment 3.

### DETAILED DESCRIPTION OF THE PREFERRED EMBODIMENTS

The present invention has utility for a design and process for photo-active devices incorporating nano-elements positioned in an array. The inventive process employs nano-element template imprinting, nano-element direct imprinting, the nano-printing technique of nano-stamping, or combinations thereof.

Variations may be applied to metallic or non-metallic nano- elements. The design and process are applicable to substrate or superstrate cell configurations in one sun and concentrator uses. By way of example, photo-active devices formed according to the present invention include solar cell photovoltaics, photosynthesis devices, and light detection devices. Nano-imprinting lithography for defining LCCM nano-scale electrode element structures of this invention permits low cost, manufacturable nano-scale pattern generation. The nano-imprinting process coupled with nano-element transfer of this invention is new and highly efficient. The invention embodiments disclosed here all have the following advantages over other techniques for producing structures incorporating nano-element metallic or non-metallic arrays for light trapping: the new approach (1) does not need a dry-etching step for cleaning the bottom of an imprinted pattern; (2) can use high process temperature during the following process steps; (3) does not use an etching step to define the nano-elements and their array, and (4) does not need an etching step for removing the deposited base portion of any nano-element array material. The approach disclosed here for manufacturing not only reduces the number of vacuum-based processing steps, but also offers more freedom in selecting process conditions for subsequent steps. These potential advantages combined with the capabilities of high throughput with low cost production offered by roll-to-roll processing critically contribute to low cost manufacturing by the present invention, and offer market competitiveness advantages.

This new fabrication approach for creating nano-scale array structures for photo-active devices will be specifically discussed in the context of solar cells. However, the present invention has application to various photo-active devices producing or utilizing light, the latter including solar cell photovoltaics, photosynthesis devices, and light defection devices.

In particular roll-to-roll nano-imprinting and printing, roll-to-roll processing, or combinations are used in the inventive process. An array of nano-scale electrode element structures is used as, or as a part of, one of the electrodes as a component of an LCCM device. This inventive component array penetrates into a light absorber layer (e.g., amorphous silicon (a-Si:H)) or, more generally, into an active layer containing at least one absorber. The unique architecture of the resulting LCCM devices decouples the directions of light absorption and photo-generated carrier collection, and thereby allows the inventive devices to take better advantage of the available light while providing efficient carrier collection. An inventive LCCM device in certain embodiments offers significantly higher power conversion efficiencies (PCE) than cells utilizing the “sandwich like” planar architecture employed in many conventional solar cell devices [11]. An inventive LCCM a-Si:H single junction solar cell device has attained about 8.2% in PCE which is the highest PCE among the solar cell devices employing nanotechnology, and even though an anti-reflection (AR) coating was not employed [6].

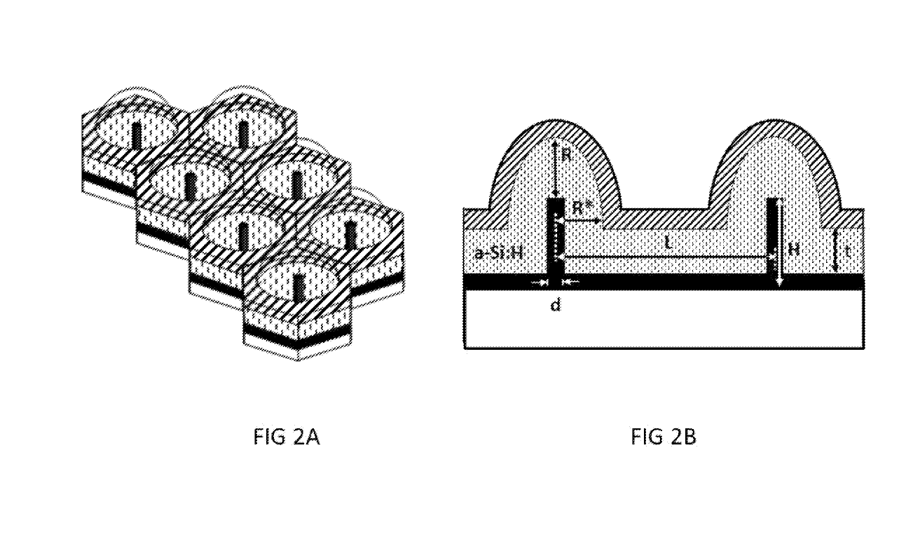

Numerical modeling of the design in FIG. 2 shows that non-metallic nano-element arrays can be at least as effective as metallic arrays, as discussed herein, and offer the ability to avoid the metal (e.g., Ag) requirements of a metallic array. Both non-metallic and metallic nano-element arrays can be manufactured with nano-imprinting and printing and subsequent solar cell layer positioning, as discussed herein. Both are the subject of the processing innovations disclosed.

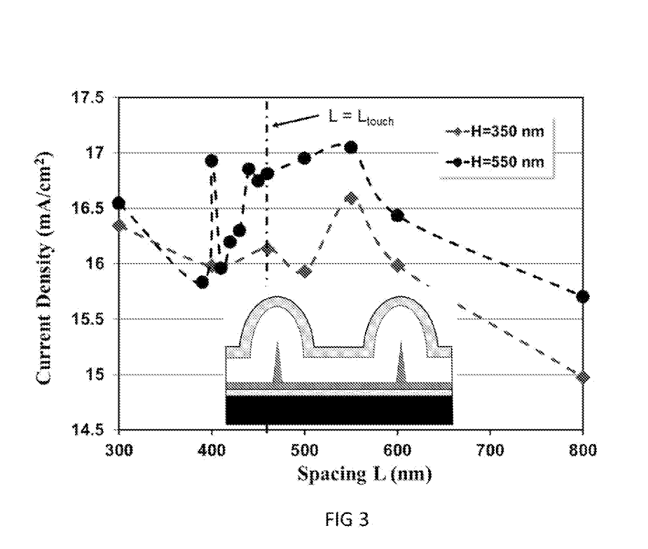

The general architecture of FIG. 2 can be seen to include the substrate architecture of the inset in FIG. 3. The architecture of this inset has the following features:

(1) It is substrate cell design with a transparent conductive nano-element array positioned on a planar back reflecting conductive (e.g., metal) electrode. This avoids excessive use of Ag and allows nano-imprinting or stamping [8, 9, 16, 17] of organic or inorganic transparent conducting nano-elements onto this planar surface.

(2) It uses conformal cell layers positioned on the nano-elements (These can all be deposited in one pump-down, if vacuum deposition is used).

(3) It can insure that all photocarriers can access their respective electrode surfaces.

(4) It can be fabricated with imprint or print lithography techniques and can be fabricated using roll-to-roll processing.

These features of an inventive structure underscore the use of conformality and of transparent conductive (e.g., transparent conductive oxides (TCOs), transparent conducting organics) nano-elements. As seen in FIG. 2, these are centered in unit cells, which may be hexagonal. In the case of this substrate solar cell, these unit cells are sitting on a planar reflector (e.g., Ag) surface. Numerical modeling assessments have been performed using the commercial optics code Ansoft HFSS and have demonstrated the performance capabilities seen in FIG. 3. Here the TCO nano-elements are taken to be the TCO aluminum zinc oxide (AZO) cones with an AZO base and sitting on a planar Ag layer. For the purposes of demonstration, the absorber is taken to be a-Si:H giving an active layer in a p-i-n configuration. Other nano-element shapes and materials are possible and other absorber (e.g., nc-Si, CdTe, iron pyrite, organics, copper indium gallium selenide (CIGS), dyes, quantum dots) and carrier collection approaches (e.g., p-n, surface barrier, dye sensitized solar cell) are also possible.

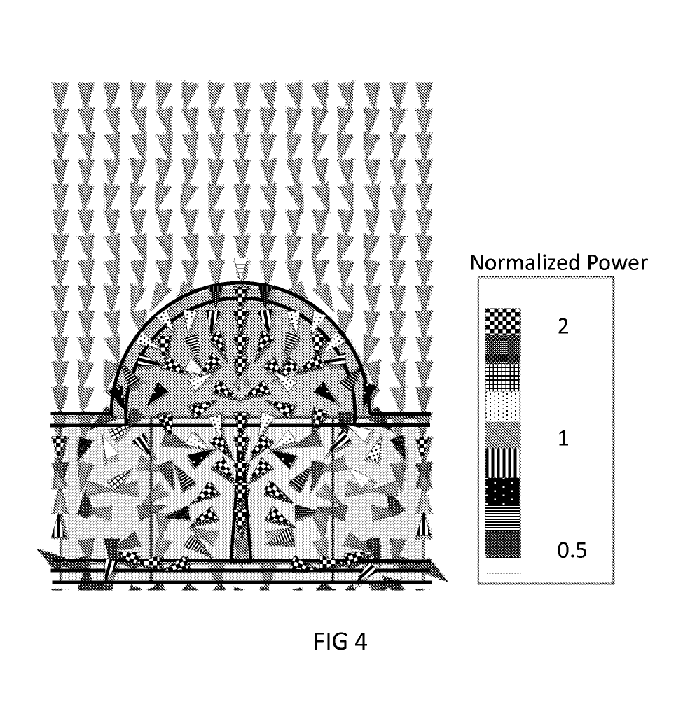

In the modeling results of FIG. 3, the anode of the p-i-n a-Si:H device is 80 nm AZO. The a-Si:H R, R*, and t parameters are 200, 150, and 200 nm, respectively, while the AZO nano-cone parameters are d=100nm and H=350 or 550 nm. The AZO nano-cone array is sitting on 30 nm of planar AZO coated onto the planar Ag film. This AZO coating on the Ag serves as a spacer layer and as an electron transport/hole blocking layer (ET/HBL) at the cathode. As seen for the results of FIG. 3, this analysis shows the design can raise J_{SC} to 17.1 mA/cm² for nominally 200 nm a-Si:H substrate cells thereby increasing short circuit current density by 54% over the J_{SC} (11 mA/cm²) attainable by the corresponding 200 nm a-Si:H planar control. An examination of the geometry for this case shows that this J_{SC} is achieved with all the a-Si:H photocarrier generation occurring within 224 nm of a collecting electrode surface. This value insures photocarriers can be collected to their respective electrodes. Importantly, the point is that this non-metallic nano-element array/planar reflecting conductor substrate design is quite capable of very effective light and carrier collection management. It should be noted that this enhanced J_{SC} possible for this substrate version of FIG. 2 is similar to that found in the modeling of the structure of reference [3]. However, (1) the array is silver in the reference [3] design and (2) the calculation of J_{sc} is elevated since it included the absorption in the Ag [3]. The guidelines for the design approach used in FIG. 2 are conveyed graphically in FIG. 4. This figure gives normalized Poynting vector (power flow) data from our numerical modeling done in this figure for the case of an nc-Si absorber. These show that our design is based on shaping the index of refraction variation so as to modify power flow at different wavelengths so as to attain a circuitous power flow in the absorber thereby increasing the optical path length and therefore absorption. Put succinctly, the circuitous power flow of the inventive structures and devices causes longer travel paths for photons in the absorber and thereby higher chances of absorption in the absorber material. As may be seen, this circuitous path effect can cause power flow to be essentially lateral (i.e., essentially parallel to the substrate) at one or more heights at cross-sections in the structure. As can be seen, the impact is so dramatic in our design based on shaped dielectrics (here the term is being used to encompass semiconductor and transparent materials) on a planar reflector (e.g., Ag) that there are places where the originally vertically impinging (light) power turns and is actually flowing at or near to essentially laterally; i.e., parallel to the substrate. Our design works to have this occur at various wavelengths thereby increasing light trapping and thereby increasing the probability that light absorption is enhanced at those wavelengths. Typical dimensions for an inventive structure are as follows: R=5 nm to 5000 nm nm; R*=5 nm to 5000 nm, t=5 nm to 5000 nm; d=10 to 500 nm, and H=10 to 5000 nm. The actual dimensions will depend on the active layer composition and thereby on the materials used for the absorber or absorbers as well as on the separation approach (e.g., p-i-n, p-n. surface barrier, DSSC, heterojunctions). It is appreciated that the selection of these parameters also varies depending on whether the inventive device is operating at one sun or at some concentration value.

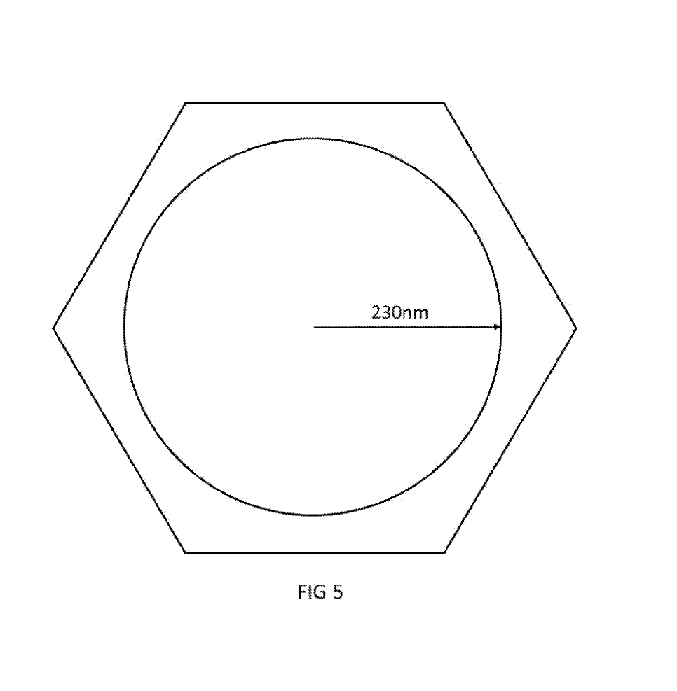

This concept of redirecting the light into circuitous paths and having locations where there can be at least some lateral flow in or into the absorber material can be utilized also in concentrator applications of the LCCM design, Taking as an example the case of the inset in FIG. 3 and using parameters to give the results of FIG. 3, it may be noted that the a-Si:H absorber is only 200 nm thick in the areal region outside domes, (See FIG. 2); therefore the principal source of the large short circuit current density seen in FIG. 3 is light entering through the domes. Light entering through the region among the domes is essentially only giving a short circuit current density of J_{SC}=11 mA/cm². The top view given in FIG. 5 shows how this fact may be exploited in an optical concentrator configuration. The hexagon in this figure is the top view of one of the hexagonal unit cells of the solar cell of FIG. 2 and FIG. 3 for the case of L=550 nm.

The circle denotes the top view of the dome of radius ˜230 nm that is present in this hexagon for this L=550 nm case. A straight forward calculation of the area of this hexagon gives 2.6×10⁵ nm², while the same calculation for the circle gives 1.6×10⁵ nm². Consequently ˜1.0×10⁵ nm² of the area in this top view of this example is not contributing as significantly as it could to the short circuit current density. Put another way, 38% of the incoming light per hexagon is not channeled through the dome structure of this example and is not experiencing total redirection into the circuitous paths seen in FIG. 4. This may be overcome by placing a concentrator lens system on the hexagon of this example—and on each hexagon of the LCCM cell array. This lens system then optimally concentrates all the light impinging on the 2.6×10⁵ nm² of this example into the dome top area of 1.6×10⁵ nm². This allows the short circuit density and therefore the cell power conversion efficiency to be increased. Using the estimate of the added area, the conversion efficiency could be increased by up to 63% for the hexagonal spacing of L=550 nm. Indeed increases are possible for all L values >L_{touch}; and for configurations other than hexagonal. Since the short circuit current density of the non-concentrator cell is ˜17 mA/cm², the concentrator LCCM cell of FIG. 4 offers a short circuit current density of ˜27 mA/cm². This analysis is obviously very approximate and gives an estimate which is an upper bound. It assumes the lensing can focus all the light impinging on the area outside the circles into the domes and scales the value ˜17 mA/cm² of the non-concentrator cell as if all the additional light were impinging essentially normally (perpendicularly) onto the domes; i.e., in a direction close to that of normal (perpendicular) direct sunlight impingement.

This will be attainable to varying degrees depending on the lensing system details and the direction of the incoming sunlight itself. While these numbers give upper bounds, it is clear that this concentrator LCCM cell offers enhanced performance in short circuit current and power conversion efficiency. The lensing here is an example of the use of micro-optics [10] and the lens materials may be formed of glasses, organics, or some combination thereof. The formation of the lens for each hexagon optionally occurs through the use of imprinting or stamping. The dome shape of the basic LCCM substrate cell may be used in aiding in the lens shaping. An alternative to optical lensing concentration is luminescent solar concentration. In this case at least the area outside the dome of our example would be covered with a film containing luminescent entity (quantum dots, molecules) to direct light into the domes.

In discussing the manufacturing of these LCCM cells, both non-concentrator and concentrator versions, it is noted that the nano-element array in FIG. 2 and FIG. 3 is non-metallic (AZO in this example) but positioned on metallic reflector (in a substrate configuration) which may be covered with a planar transparent conducting material (AZO in this example). However, the manufacturing approaches to now be discussed apply also to cases where the configuration may be that of a substrate or superstrate solar cell and the nano-element array may be metallic. In all cases, the manufacturing of LCCM cells must address through-put and cost issues. Three exemplary inventive embodiments for effective manufacturing which address these issues are now disclosed.

In one embodiment of the fabrication of LCCM type devices, the formation of the 2-D nano-element array uses an imprint resist which is patterned into an array of voids in the resist, the pattern of template voids being formed in the imprint resist by nano-imprinting. A conductive material is then disposed in the template voids of the resist to form the nano-elements arrayed in 2-D (i.e., a 3-D nano-element array periodically laid out in 2-D as in FIG. 2.) and a base of conducting material is further disposed to give electrical communication among the multiplicity of the nano-elements of the array until all the surface of the imprint resist is sufficiently covered by a conducting layer. In some configurations these two disposed materials may be the same. In some configurations one or both must be transparent. In some configurations the base must also provide mechanical stability. In substrate configurations the base or a material positioned between it and the final substrate must be reflector (e.g., Ag). A second (final) substrate is then put into contact with the base or base plus reflector and used to support the array of nano-elements encased in the imprint resist and the base which is covering the elements as well as covering the previously exposed resist surface. The array of nano-elements are dimensioned by the formation thereof in the imprint resist and these elements and their base are transferred to the second substrate and the resist removed (e.g., dissolved). This second substrate may be the final device substrate and may be formed of materials such as metals and metal foils, plastics, glass and glass foils. The array of nano-elements and its base may be adhered to the substrate surface. In some configurations, there is an adhering material which may or may not be conducting. The substrate may also have a conducting layer thereby allowing it to support the electrical conduction of the nano-element array and base.

To complete an inventive device some combination of layers are disposed on the array. These layers are illustratively selected from among doping layers, spacer layers, light absorber layers, a counter electrode and a combination of these various layers.

In a second embodiment the formation of the 2-D nano-element array is effected by directly imprinting the 2-D nano-element pattern into a planar layer of the nano-element or nano-element precursor material situated on a substrate. This nano-element material may have sublayers of various compositions. These imprinting results in a 3-D nano-elements arrayed in a 2-D pattern in the nano-element material and may be done to also insure a continuous base layer of the nano-element material is preserved among the nano-elements. The nano-element material, and base layer, if present, (or their precursors) are to be inherently, or to be rendered, conducting and, in superstrate applications, transparent during or at the conclusion of processing. The base resides on the substrate. The base may be transparent or a reflector. The imprintable material which becomes the nano-elements, and in some configurations, the base may include materials such as inks, sol-gels and organics. The sol-gels are formed, for example, from materials such as Al doped zinc oxide (AZO) and indium doped tin oxide (ITO).

In the second embodiment the substrate initially holding the un-patterned nano-element material is the final device substrate and may be formed of materials such as metals and metal foils, plastics, glass and glass foils, This substrate may also have a conducting layer on its surface thereby allowing it to support the electrical conduction of the nano-element array and base. Doping layers, spacer layers, a light absorber or absorbers, and a counter electrode are disposed conformally on the nano-element array to complete the photo responsive device.

In a third embodiment, the formation of the 2-D nano-element array uses a template substrate containing a pattern of array template voids, the pattern of template voids having being formed in the template substrate by any of a variety of lithography and etching procedures such as photo-lithography, e-beam lithography, or imprinting combined with wet or dry etching, as may be needed. A conductive material is then disposed into the template voids of the template substrate to form the 2-D nano-element array and optional base. A final substrate is then put into contact with the nano-elements or their base, if present, and used to support the array-base nano-element structure positioned on the template substrate. This substrate may be formed of materials such as metals and metal foils, plastics, glass and glass foils. The array of nano-elements and its base may be adhered to the final substrate surface for integrity and for enhancing separation from the template substrate. In some configurations, there is an adhering material which may or may not be conducting. This substrate may have, if there is a base, and must have, if there is no base, a conducting layer thereby allowing it to support the electrical conduction of the nano-element array and base. If a superstrate configuration is being used, then of course this conducting layer, base, and nano-elements must be transparent. Doping layers, spacer layers, a light absorber or absorbers, and a counter electrode are disposed conformally onto the array-base structure on the final substrate as needed to complete the photo responsive device.

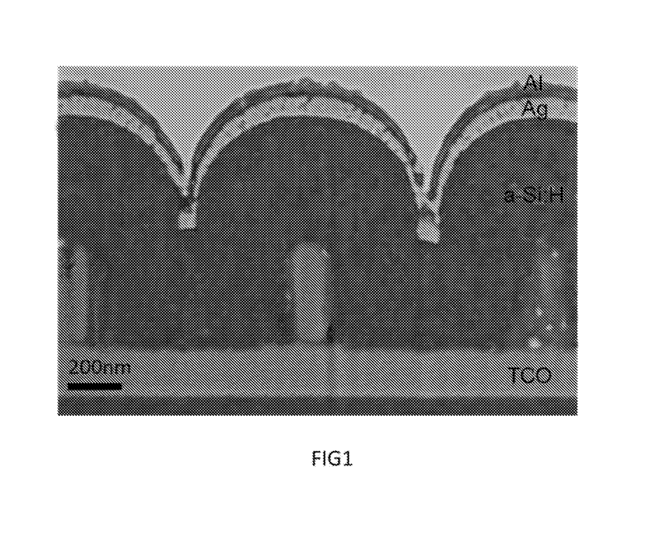

As noted earlier, FIG. 1 shows the cross sectional field omission scanning electron microscopy image of an inventive LCCM device for the example of a superstrate configuration. The nano-scale columnar electrode structures of this example are formed on a transparent conducting oxide (TCO) covered glass substrate using e-beam based processing. The dimensions of the structures are 150 nm in diameter, 400 nm in height, and 800 nm in spacing (edge to edge of the columns) and they are at the center of unit cells arranged in this example in a hexagonal pattern giving a triangular lattice array. It is appreciated that other array patterns are operative herein and these illustratively include rhombic, square, rectangular, and oblique. When referring to nano-element dimensions, the term diameter refers to the maximal lateral dimension of column and cone-like elements. Nano-elements may have various shapes (e.g., cones, columns) and their dimensions (height and largest lateral dimension) are typically from 10 to 5000 nm and 10 to 5000 nm, respectively, with nano-element spacings typically from about 50 to 5500 nm. After establishing these nano-scale elements (columnar structures, as seen in the example of FIG. 1), active p, i, and n layers of a-Si:H are sequentially deposited and then an Ag/Al counter electrode is formed in the case of FIG. 1. In general, the active layer includes at least an absorber material and may be configured to be any of the standard configurations of p-i-n, p-n, dye sensitized, or surface barrier solar cells known in the field. The p-i-n and p-n cells may be homojunctions or heterojunctions. The absorber is optionally one of a semiconductor, a dye or quantum dots. The structure of the example of FIG. 1 or FIG. 3 results in a highly effective photon distribution in the absorber, thereby producing strong light absorption, and simultaneously allowing photo-generated carrier harvesting from throughout the absorber volume.

As noted, e-beam pattern generation for nano-element array production is not a manufacturable approach for mass production solar cells. Nano-imprinting of the present invention can pattern large areas at one time and is compatible with roll-to-roll processing. Traditional nano-imprinting, however, has drawbacks when considering usage thereof to produce the nano-element array needed for the LCCM photo-response device architecture. For example, if the nano-imprinting is used to define empty template regions which are to filled to become the nano-elements, nano-imprinting techniques cannot define patterns all the way down to a substrate using a single imprinting step. At least one dry-etching step for either cleaning the residues on the bottom of the pattern or transferring the pattern further down to a substrate is required [12,13]. The concepts disclosed herein avoid such problems.

### Embodiment 1

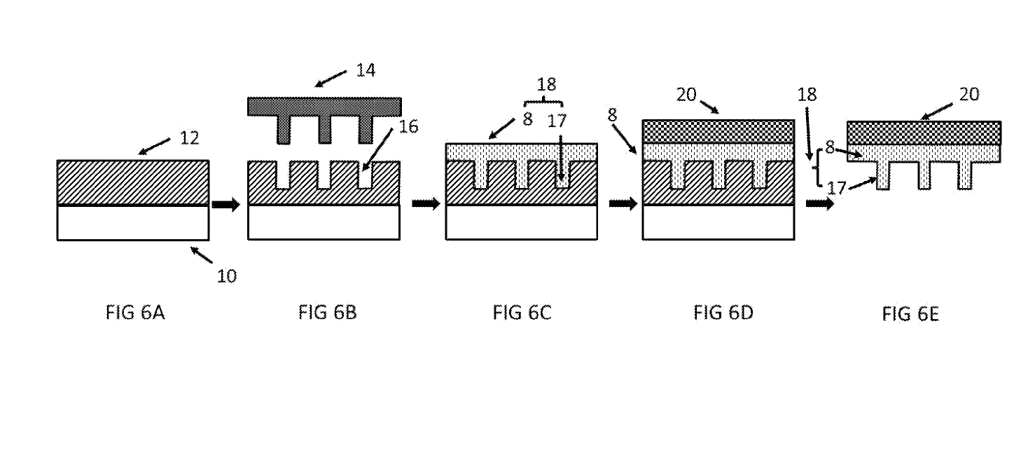

A first embodiment of the fabrication of LCCM type devices disclosed herein uses an imprint resist material which is patterned with an array of template voids in the resist material. The pattern of template voids is formed in the imprint resist material by nano-imprinting. The overall process is pictured in FIGS. 6A-6E. It is appreciated that in this process the pattern may be applied by a roller or by stamping such as by multiple heads or a plate. The process is also operative as a batch-like process.

In embodiment 1, a first substrate 10 is coated with an imprint resist material 12. An imprinting tool 14 with a mold pattern, to yield a template void array 16 into the resist material 12 upon contact. This template 16 in the resist material 12 is to be filled with material to obtain an array with the desired nano-scale features and spacing 17. The nano-scale featured and spaced material nano-element array 17 is attained by disposing material or materials 12 into the template void array 16 giving the result seen in FIG. 6C. The nano-element array innovative base 8, together with nano-element array 17 constitutes the nano-element structure 18, The nano-element structure 18 connects the nano-elements physically together and if the elements of the array 17 are electrically conductive, then the base 8 optional interconnects the elements of the array 17 electrically. Overall thickness of a base 8 is generally controlled by its disposition processing time (e.g., physical vapor deposition, chemical vapor deposition, laser ablation, electro-plating, and spray pyrolysis).

The inventive process further overcomes the limitations of the prior art by then transferring the disposed nano-element structure 18 to a second substrate 20. This transferal is accomplished by separating the filled template 16 from the structure 18 through techniques such as dissolution (e.g., water soluble), chemical attack, thermal decomposition, or mechanical separation. The innovative usage of a second substrate 20 offers more flexibility (1) in the choice of the second (final solar cell) substrate, and (2) in the process conditions during subsequent fabrication steps. For example, in the case of a-Si:H solar cell devices, the process temperature of the film depositions onto the nano-element structure is critical. The quality of the films is sensitive to deposition temperature and to the temperatures associated with later processing [14]. The processing approach of the present invention allows for transferring the nano-element structure from a first “mother” substrate to a second (or final) substrate (e.g., glass substrates, plastics, metal foils) that can be selected to be compatible with the processing temperatures needed for further processing.

The novelty of the embodiment allows the use of imprinting for the creation of shapes such as cones which could not be achieved without the required separation step inherent in this processing flow. The novelty of the present invention also precludes commonly encountered etch and cleaning steps affording simplicity of processing, cost savings, and removing environmental concerns of etch waste disposal. For example, an etch step normally occurs after the nano-scale electrode elements have been formed in the void regions of the template of FIG. 6B. As shown in FIG. 6C, in such conventional imprinting or stamping processing there is extra material on the resist surface, as well as resist itself, among the nano-elements. It is necessary in conventional processing, which generally uses the initial substrate only, to remove the material residing on the template resist top surface. In the present invention, this “excess” material, is exploited and may be augmented in base 8 formation to give the required nano-element structure 18 conductivity and mechanical integrity. In conventional processing, the template resist among the nano-elements is also removed generally before further processing.

After disposition of any optional additional conducting material to insure the mechanical stability and electrical continuity between array elements of the nano-element array 17 (i.e., after base augmentation as needed), the resulting structure is bonded to the second (final) substrate 20 seen in FIG. 6D thereby allowing its removal from the mother substrate 10 in FIG. 6E. It is appreciated that a second substrate 20 may be alternatively achieved by disposition (e.g., laser ablation) of substrate material onto the base 8. Once the nano-element structure 18 is on the final substrate 20, the other device layers discussed above are deposited to complete a LCCM device. These added layers illustratively include some combination of dopant, spacer, selective transport (e.g., hole blocking/electron transport), absorber, and counter electrode (e.g., reflector electrode (for superstrate cells), and transparent electrode (for substrate cells) layers, as required by the configuration and substrate or superstrate designs. The final cell may be a substrate or superstrate device configuration, such as a solar cell depending on the substrate transparency, base transparency, and the selections made for these layers discussed above.

Nano-imprinting techniques operative herein illustratively include approaches that may employ hot-embossing and UV radiation exposure in the pattern definition process needed on the mother substrate 10 (FIG. 6B). As noted, this imprinting is done into the imprint resist 12 to form the template for the nano-element structure 18. The resulting imprinted resist 12 should have reflow properties that do not allow unacceptable reflow during the following nano-element array material 17 and base material 8 production. After the pattern definition step of FIG. 6B creating the empty templates, a filling process such as, by not limited to, sputtering, laser ablation, or atomic layer deposition (ALD) is used to fill the empty template regions with conducting material such as a metal or a transparent conductive material such as a transparent conductive oxide (TCO), or an organic with similar complex index of refraction properties to a TCO such as the organic poly (3, 4-ethylene dioxythiophene) (PEDOT). Preferably, the conducting material is transparent. It must be transparent for superstrate solar cells. By way of example, if aluminum zinc oxide (AZO) is used as a TCO for this filling step, it is found to work quite effectively, as seen in FIG. 1. The AZO film does not react with hydrogen containing plasmas which is very advantageous if such plasma are involved in subsequent processing, This is especially advantageous when using materials such as plasma enhanced chemical vapor deposited (PECVD) a-Si:H or nc-Si. Subsequent to the filling step, the nano-element material may be cured, if necessary, prior to or after base disposition. This curing may be undertaken using techniques illustratively including heating, UV radiation, radiation heating, and rapid thermal annealing (RTA). The filling process (e.g. sputtering. laser ablation, CVD, PVD, or ALD of AZO) can be continued to produce the base 8 thereby making a mechanically stable nano-scale element array as seen in FIG. 6C. This base 8 may be made of any conducting material in general, and it is appreciated that the base need not be transparent in the case of substrate architectures.

In the case of a substrate cell, the base 8 is optionally configured as a conducting Bragg stack reflector or conventional metallic reflector readily formed of a metal (e.g., Ag, Cu, Au, Al, or alloys containing one of the aforementioned metals). In the case of a superstrate cell, the base 8 must be both conducting and transparent (e.g., a TCO or appropriate TCO equivalent organic). This continuation may be done by sputtering or ALD but it is appreciated that other deposition and growth approaches illustratively including plasma ablation, spray pyrolysis, CVD, and other PVD techniques are also operative in adding or augmenting the base 8. At the conclusion of this base completion, the whole nano-element structure 18 is transferred (FIG. 6D) to the second (final) substrate (e.g., glass, metal, organic including polyimide and polyethylene). There is a range of materials (e.g., adhesives, UV curable adhesives) and process steps (e.g., roll laminating and anodic bonding) that may be employed for transferring the nano-element structure to the second substrate 20. Alternatively, the second substrate 20 itself is deposited in the step depicted in FIG. 6D by a fast CVD or PVD process (e.g., spray pyrolysis, plasma ablation).

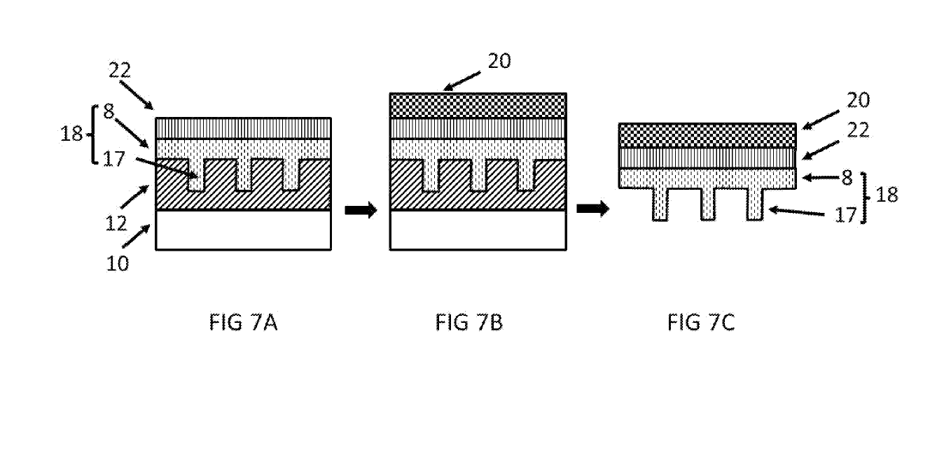

As shown in FIGS. 7A-7C, a transfer process is depicted using an adhesive material 22 intermediate between a final substrate 20 and nano-element structure 18. Like reference numerals used in FIGS. 7A-7C have the meaning associated with those numerals with respect to FIGS. 6A-6E.

If a material is used to adhere the base to the final substrate (see FIGS. 7A-7C), the choice of this adhesive material for attaching the base with its protruding nano-elements (on the non-adhering side) to the final substrate depends on the conduction abilities of the base material, whether or not the final substrate is being utilized for the cell contacting and electrical conduction, and on whether a substrate or superstrate cell is the objective. If the base 8 suffices for transparency and cell contact and electrical conduction purposes in a superstrate cell, then the adhesive material 22 need only supply transparency and mechanical attachment to the final substrate 20. The adhesive material 22 must also be conductive if the final substrate has been prepared to play a role in cell contacting and electrical conduction. If the base layer 8 suffices for cell back reflection, cell contact and electrical conduction purposes in a substrate cell, then the adhesive material 22 need only supply mechanical attachment to the final substrate 20. The adhesive material 22 must also be conducting if the final substrate has been prepared to play a role in cell contacting and electrical conduction in a substrate cell architecture. In general, the transfer process to the final substrate 20 (e.g., glass, metal, polyimide, polyethylene naphthalate (PEN), polyethylene ter-phthalate (PET) necessitates good adhesion between this second substrate 20 and the base layer 8 of the nano-element structure 18 encased in the imprint resist 12. This transfer process of FIG. 6D and E can be done by an adhesion process as shown in FIGS. 7A-7C and includes (1) application of an adhesive material 22 (e.g., by spraying, “doctor's knife”, etc.); (2) bonding of the second substrate 20 and the base 8 by the adhesive material 22; and (3) complete transferring of the nano-element structure 18 to the second substrate 20.

Whether a bonding layer of some type is or is not used, at least two paths may be taken to separate from the mother substrate 10 upon transfer to the final substrate 20. One exemplary route is to chemically remove or dissolve the imprinted resist 12 bearing the nano-element array 17 and base 8 in a solvent, so substrates 10 and 20 are separated and released as the layer 12 is removed. The resist may be removed by standard resist removal techniques. In addition, it may be chosen to be water soluble for ease of dissolution or may thermally decompose for removal.

The second route is to mechanically separate the substrates 10 and 20. Cleaning steps are optionally used after separation to prepare the now free surfaces of the nano-element structure 18 for subsequent disposition of the essentially conformal layers required to complete a substrate or superstrate solar cell. Such conformity is attained by adjusting the processing parameters of the technique chosen as is well known in thin film work.

It is also possible to have substrate 20 be a temporary substrate and to transfer first to this temporary substrate which is selected for processing compatibility such as tolerance of high temperature absorber deposition temperatures. These temporary substrates may include metals or metal foils to allow high temperature processing. After such use of a temporary substrate, the array could be moved to or attached to a final substrate by the approaches discussed for moving to substrate 20. These include dissolving, chemically removing, or thermally decomposing the temporary substrate after adhering to the final substrate.

It is appreciated that roll-to-roll processing may be used in this embodiment to imprint and/or transfer nano-element structures.

### Embodiment 2

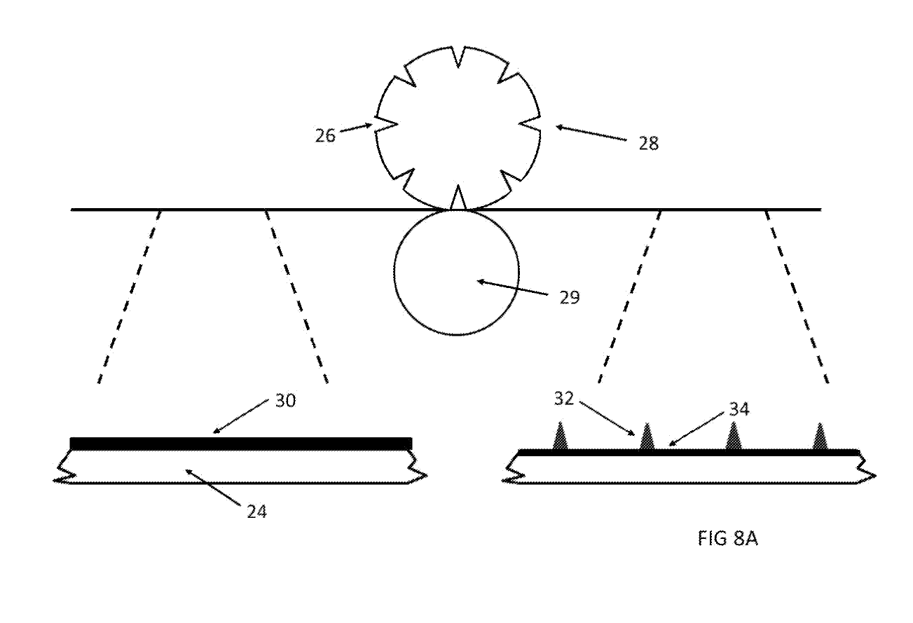

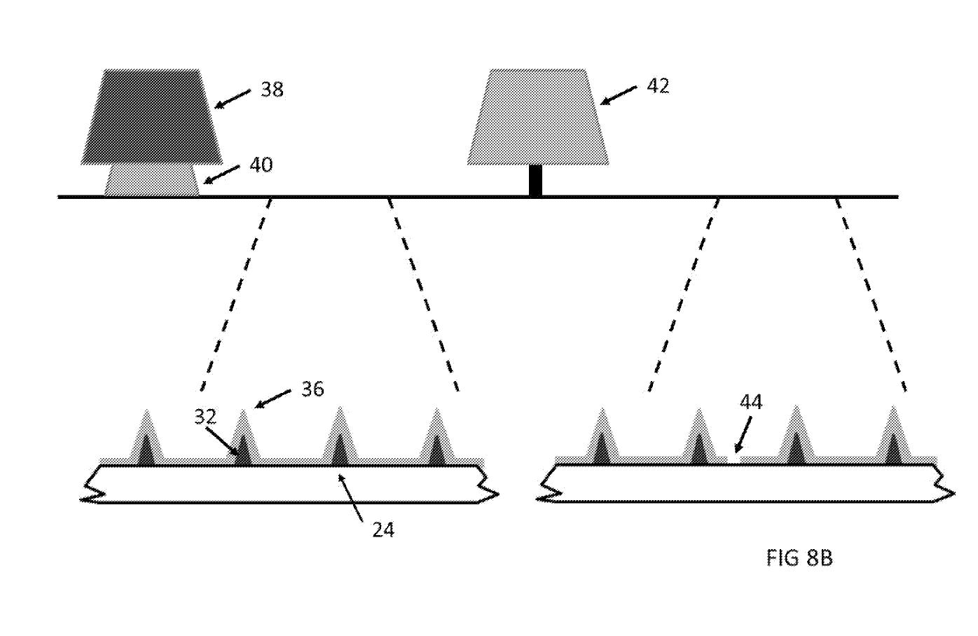

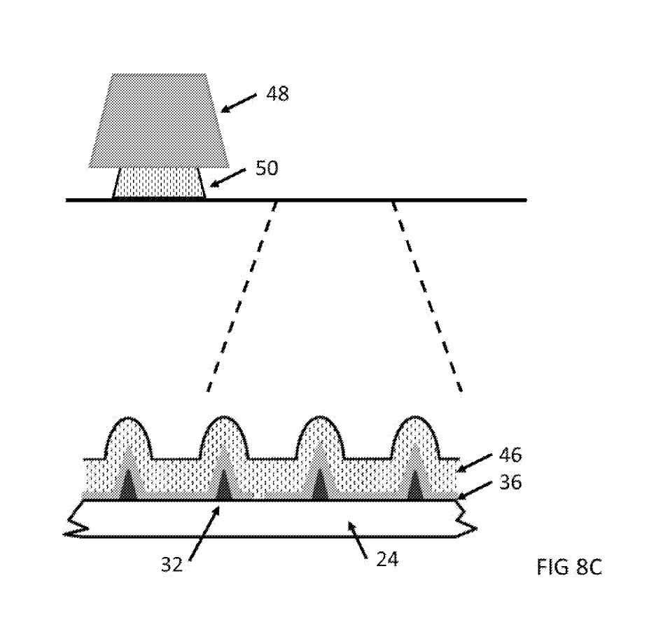

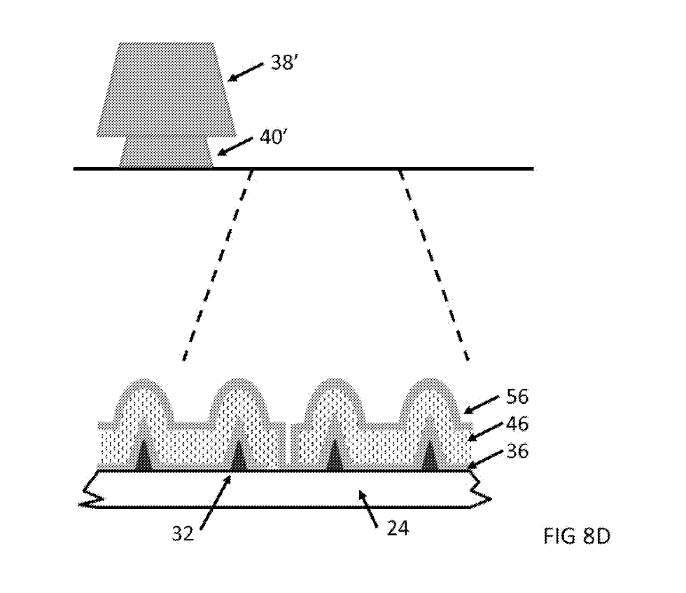

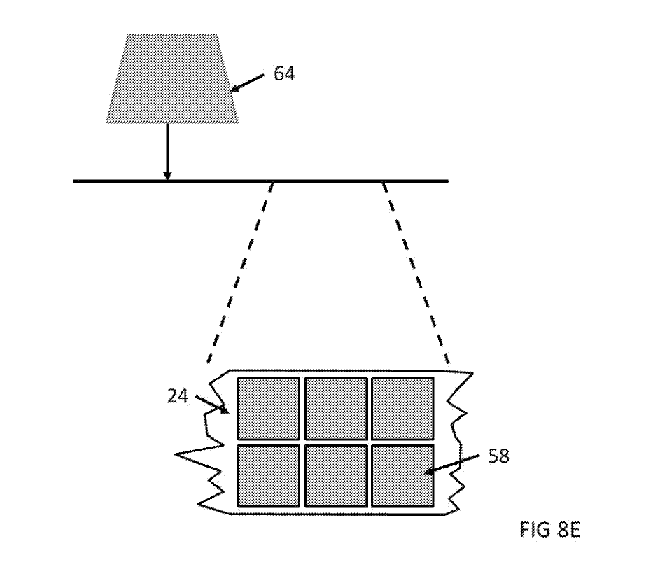

Nano-imprinting techniques are used in another embodiment of the invention for direct pattern definition as shown in FIG. 8A. While the use of a roll-to-roll processing is discussed for embodiment 1, a roll-to-roll process is explicitly shown here for embodiment 2. It is appreciated that in this process the pattern may be applied by a roller or by stamping such as by multiple heads or a plate. The process is also optionally a batch process.

In FIG. 8A, final substrate 24 is a material such as a sheet, tape, foil, or ribbon and is formed from materials illustratively including stainless steel, aluminum, glass, and polymeric materials. This final substrate is coated with a planar material 30 which will become the nano-elements and base, if used. An imprint pattern 26 defines a template which creates the nano-elements by contact. It is depicted on a mold roller 28 operating in conjunction with an anvil roller 29. It should be appreciated that this depiction 26 in FIG. 8A is not to scale. As pattern 26 is impressed into a nano-element material or its precursor material layer 30, an array of nano-elements 32 is formed. The nano-element or nano-element precursor material (nano-element material 30) has temperature dependent and light properties suitable for the subsequent processing. It should be chosen to limit undesired reflow in subsequent processing. After or during the imprinting step, the nano-element material may be cured, if necessary, using techniques illustratively, including radiation, heating, and rapid thermal annealing (RTA). The nano-element material 30 may be a metallic substance (e.g., an ink). Non-metallic materials 30 into which the nano-elements 32 are directly imprinted illustratively include transparent conducting sol-gels (e.g., ITO, ZnO), [8, 9, 16, 17] and transparent conducting organics (e.g., PEDOT). After imprinting, a cleaning step, etching step or both can be used to remove the remaining imprinted material 34 between elements 32. Alternatively, this remaining material 34 is kept in place to serve as a base which plays the same role as innovative base 8 as described with respect to FIGS. 6A-6E. This direct imprinting to create the nano-elements from the imprinted nano-element material produces nano-elements (e.g., cones, columns) such as those depicted in FIGS. 1 and 2.

In a substrate LCCM cell configuration, these elements (nano-columns, nano-cones, etc.) may be printed in material 30 of embodiment 2 where this material 30 resides on a reflecting surface on substrate 24 (e.g., containing a Bragg stack or a metal). In a superstrate LCCM cell configuration, these elements 32 may be printed onto a transparent surface of a transparent substrate 24. If the remaining material 34 among the nano-elements (i.e., the base) is retained and of sufficient conductance, then the surface of the substrate 24 need not be conducting. Material 30 and remaining material 34 must be transparent for a superstrate cell. In embodiment 2, the free surfaces of the nano-elements 32 and base 34 are immediately ready for subsequent deposition of the essentially conformal layers required to complete a substrate or superstrate solar cell. Such conformality is attained by adjusting the deposition technique and parameters as is well known in thin film work. If a transparent substrate is used (e.g., glass, glass foils, or transparent plastics) in this processing flow as the substrate 24, then the processing may be used to produce a superstrate cell-type. If an opaque substrate (e.g., metal, metal foil, metal coated plastic or metal coated glass) is utilized as the substrate 24, this processing produces the substrate cell-type seen in FIG. 2.

As shown in FIG. 8B, the substrate 24 with imprinted nano-elements 32 attached thereon then begins, as in the other embodiments, the steps required for the disposition of the remaining substrate or superstrate solar cell structure. This may begin by including, for example, deposition of an electron transport/hole blocking or hole transport/electron blocking material (e.g., an organic or TCO), as appropriate, spacer/transport control layer 36. As shown in FIG. 8B, this disposition source is depicted at 38 with the material stream being shown at 40 with the magnified cross-sectional view of the substrate encodings below. For visual clarity the remaining base material 34, if present between the nano-structured elements 32 is not shown in FIGS. 8B-8E, even though the presence of remaining material 34 does not affect the subsequent processing steps depicted in these figures. Optionally, a first cell definition (i.e., isolation) procedure is performed as shown in FIG. 8B by the apparatus 42 to create a gap 44 in the coating 36 and remaining material 34 and any conducting layer thereunder if present. Such an isolation procedure is shown as an example only and isolation steps may occur here or wherever dictated by the particular cell interconnecting scheme and processing details being utilized. Such isolation steps may also be part of embodiments 1 and 3.

FIG. 8C depicts the disposition of solar cell dopant/absorber layers 46 onto coating 36 serving as a spacer/transport control layer overlying nano-elements 32 and base 34. An apparatus for this task is shown schematically at 48 with a coating material stream being shown schematically at 50. FIG. 8D depicts a further step to dispose a second conducting organic or inorganic layer 56, This layer may be a conducting optical spacer/transport control layer which is then followed by a reflecting and preferably conducting coating (superstrate cell) or a conducting optical spacer/transport control layer which then is followed by a transparent, conducting coating (substrate cell) It is appreciated that transparent conducting organic or inorganic coating 36 and layer 56 need not be of the same material or thickness. The disposition apparatus and disposition stream for layer 56 are shown schematically in FIG. 8D at 38′ and 40′, respectively. In the case of superstrate solar cell architectures, this layer 56 step must be followed by application of a reflector such as an Ag layer.

FIG. 8E shows schematically an apparatus 64 for an example of grid creation on the substrate 24 producing the exemplary grid 58 seen. In contrast to the substrates depicted in FIGS. 6A-6E and 7A-7C, in FIG. 8E, a top view of the substrate 24 is provided. As with isolation, grid formation may be included in the processing for embodiments 1 and 3.

### Embodiment 3

The characteristic feature of embodiment 3 is the use of a template, containing all of the array patterning information, positioned in a template substrate. This template substrate may be employed in one of two approaches to form the nano-element structure. In either, the template substrate is preferably a metal or polymer ribbon-like roll-to-roll band. If this template substrate is reused after separation, reuse may be undertaken after appropriate cleaning and reapplication of an anti-sticking (i.e., release) agent, as needed, to enhance nano-element structure separation form the template substrate.

In this third embodiment, the array template voids present on the template substrate have been formed in the template substrate by any of a variety of lithography and etching procedures such as photo-lithography, e-beam lithography, or imprinting lithography combined with wet or dry etching, as may be needed.

In one approach of embodiment 3, the nano-element material is deposited into the template of the template substrate by methods such as, for example, physical vapor deposition (PVD), or chemical vapor deposition (CVD), including spraying and laser ablation. A base of conducting material may be further disposed to give electrical communication among the multiplicity of the nano-elements of the array until all the surface of the template substrate is sufficiently covered by a conducting layer. Prior to these material dispositions, an anti-sticking agent (e.g., the fluorinated materials for this purpose from Daikin Industries) may be applied to the template substrate to enable separation of the array-base nano-element structure from the template substrate. In some configurations, the two disposed materials of the array-base materials system may be the same. In other configurations, the nano-element array (substrate cell) or both (superstrate cell) must be transparent. In still other configurations, the base must also provide mechanical stability. In substrate cells, the base must be a reflector (e.g., Ag) and/or the substrate onto which it is attached must have a planar reflecting metal surface. The array of nano-elements is dimensioned by its formation in the template substrate.

A second substrate is then put into contact with the base with the objective of eventually supporting the array-base materials system positioned on the template substrate, This second substrate may be the final device substrate and may be formed of materials such as metals and metal foils, plastics, glass and glass foils, The array of nano-elements and its base may be adhered to the second substrate surface for integrity and for enhancing separation from the template substrate. In some configurations, there is an adhering material which may or may not be conducting, as described in the prior embodiment discussions. The second substrate may also have a conducting layer thereby allowing it to support the electrical conduction of the nano-element array and base. The use of reflecting materials and conducting materials on this substrate and/or the base, as dictated by the requirements of substrate or superstrate configurations, is determined as discussed in Embodiments 1 and 2.

Doping layers, spacer layers, a light absorber or absorbers, and a counter electrode, with properties as required by a substrate or superstrate cell, are disposed conformally onto the array-base structure on the second substrate to complete the photo responsive device.

In certain embodiments, the template substrate is a constantly reused, metal or polymer ribbon-like roll-to-roll band.

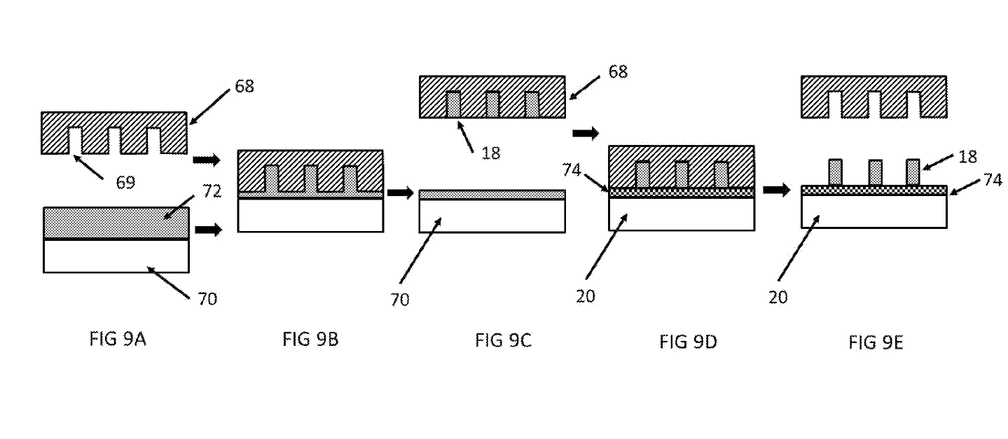

In this embodiment 3 of the present invention, the second approach of using the template substrate concept is seen in FIG. 9A. As before in the first approach of embodiment 3, the nano-element array template is defined in the template substrate which is here shown as 68 in FIG. 9A. This template in the template substrate has voids corresponding to the desired nano-element features, pattern 69, and spacing required for the nano-element array; i.e., the template substrate has the template required such that when it is filed, the nano-element array pattern results. In this second approach of embodiment 3, this filling step is accomplished by printing the nano-element material itself or its precursor (e.g., a sol-gel or ink) into the voids. That is, the template in the template substrate is brought into contact with another substrate 70 bearing the nano-element material 72 which will become the nano-elements and the base, if utilized.

Material 72 has been applied to substrate 70 using standard disposing techniques including CVD and PVD deposition, spraying, laser ablation, or spreading. It is appreciated that the patterning of material 72 into the template pattern 69 on the template substrate 68 in FIG. 9 B is readily done by conventional equipment such as a system of printing rollers, a stamping tool, or a batch printing tool. Optionally, a mold release substance (i.e., an anti-sticking material) is applied to the template region on template substrate 68 or alternatively onto material 72 prior to printing material 72 into the mold voids of template substrate 68 to promote subsequent release between the template substrate 68 and nano-element structure formed with the patterned voids of the mold pattern 69 present in template substrate 68. It is appreciated that while the voids present in template substrate 68 will be filled with the nano-element material, the region between each void area can preferentially also be covered with material 72 thereby forming the base of the nano-element structure, as discussed above. Such a base is not shown in FIG. 9C. The template substrate 68 containing the nano-element structure 18 (which may or may not have a base) must have nano-element structure 18 separated from substrate 68.

The template substrate 68 containing the nano-element structure 18 with its optional base is then brought into contact with a third, or final substrate 20 where the above detailed embodiment 1 and 2 descriptions with respect to reference numeral 20 is applicable hereto. Removal of the template substrate 68 is readily accomplished by the techniques detailed above.

If no base is desired in the two approaches of embodiment 3, the approach of Ref. 11 may be used. This pre-coats the non-void surface of the template of the template substrate 68 with a non-wetting agent, instead of an anti-sticking agent, to avoid nano-element material disposition between the nano-elements.

The nano-element material or its precursor 72, filled into the template of template substrate 68 and its optional but preferred base, when finally transferred to the substrate 20, may necessitate a curing step to attain the required physical properties such as RTA, heating, or radiation exposure before or after being printed as the nano-element structure of an LCCM cell. This may be done at times between and including filling of the voids and after transfer. Preferably this step will be done before separation form the template substrate and its use will decrease the adherence of the nano-element structure facilitating its separation.

If the final substrate 20 is transparent (e.g., glass or transparent plastic), then the processing and material property selection may be used to produce the superstrate cell-type. If an opaque substrate (e.g., metal, metal foil, metal coated plastic or glass foil, or metal coated glass) is utilized as the final substrate 20, this processing will produce the substrate cell-type seen in FIG. 2. The processing needed to complete a solar cell, as discussed in the other embodiments, follows after the step depicted in FIG. 9E is performed; i.e., the free surfaces of the nano-elements may be immediately subject to subsequent deposition of the essentially conformal layers required to complete a substrate (FIG. 2) or superstrate (FIG. 1) solar cell. Such conformality is attained by adjusting the deposition technique and parameters as is well known in thin film work. In this second approach of embodiment 3, the nano-element material is printed into the template substrate.

Any patents or publications mentioned in this specification are indicative of the levels of those skilled in the art to which the invention pertains. These patents and publications are herein incorporated by reference to the same extent as if each individual publication was specifically and individually indicated to be incorporated by reference.

### REFERENCES CITED

1. Zhou D and Biswas R, “Photonic crystal enhanced light-trapping in this film solar cells”, J. Appl. Phys. 103, 093102 (2008).

2. Ferry V E, Verschuuren M A, Li H B T, Verhagen E, Walters R J, Schropp R E I, Atwater H A, and Polman A, “Light trapping in ultrathin plasmonic solar cells”, Optics express 18, A237 (2010).

3. Zhu J, Hsu C M, Yu Z, Fan S, and Cui Y, “Nanodome solar cells with efficient light management and self-cleaning”, Nano Lett. 10, 1979 (2010).

4. Biswas R and Xu C, “Nano-crystalline silicon solar cell architecture with absorption at the classical 4n² limit”, Optics Express 19, A664 (2011).

5. Vanecek M. Babchenko, Purkrt A, Holovsky J, Neykova N, Poruba A, Remes Z, Meier J, and Kroll U, “Nanostructured three-dimensional thin film solar cells with very high efficiency potential”, Appl Phys Lett. 98, 163503 (2011).

6. Nam W J, Ji L, Benanti T L, Varadan V V, Wagner S, Wang Q, Nemeth W, Neidich D, and Fonash S J, “Incorporation of a light and carrier collection management nano-element array in superstrate a-Si:H solar cells”, Appl. Phys. Lett. 99, 073113 (2011).

7. Catchpole K R and Green M A, “A conceptual model of light coupling by pillar diffraction gratings”, J. Appl. Phys. 101, 063105 (2007).

8. Kang Y, Okada M, Nakamatsu K, Haruyama Y, Kanda K, and Matsui S, “Room-temperature nanoimprint using sol-gel ITO film”, J. Photopolym. Sci. technol. 22, 189 (2009).

9. Dai S, Wang Y, Zhang D, Han X, Shi Q, Wang S, and Du Z, “Fabrication of surface-patterned ZnO thin films using sol-gel methods and nanoimprint lithography”, J. Sol-gel Sci. technol. 60, 17 (2011).

10. Karp J H, Tremblay E J, and Ford J E, “Planar micro-optic solar concentrator”, Optics Express 18, 1122 (2010).

11. Nam W J, Fonash S J, Liu T, and Wagner S, “A Study of lateral collection single junction a-Si:H solar cell devices using nano-scale columnar array structures”, the 35^{th} Photovoltaic Specialists Conference, Honolulu, Hi. (2010).

12. Austin M D, Ge H, Wu W, Li M, Yu Z, Wasserman D, Lyon S A, and Chou S Y, “Fabrication of 5nm line width and 14 nm pitch features by nanoimprint lithography,” Appl. Phys. Let., 84 (26), 5299 (2004).

13. Rolland J P, Maynor B W, Euliss L E, Exner A E, Denison G M, and DeSimone J M,

“Direct fabrication and harvesting of monodisperse, shape specific nano-biomaterials”, J. Am. Chem. Soc., 127, 10096, (2005).

14. Street R A, Wong W S, and Lujan R, “Low-temperature amorphous silicon p-i-n photodiodes”, physica status solidi (b), 246, 1854 (2009).

15. Battaglia C, Escarre J, Soderstrom K, Charriere M, Despeisse M, Haug F and Ballif C, “Nanomoulding of transparent zinc oxide electrodes for efficient light trapping in solar cells”, Nature Photonics, 5, 535 (2011).

16. Barbé J, Francis Thomson A, Wang E-C, McIntosh K and Catchpole K, “Nanoimprinted TiO₂ sol-gel passivating diffraction gratings for solar cell applications”, Prog. Photovolt: Res. Appl., 20, 143 (2012).

17. Park H, Zhang X, Hwang S, Jung S H, Kang S, Shin H, Kang H K, Park H, Hill R H, and Ko C K, “Simple and cost-effective fabrication of size-tunable zinc oxide architectures by multiple size reduction technique”, Sci. Technol. Adv. Mater., 13, 025003 (2012).

1. A process for forming a nano-element structure comprising:
contacting of a template and a material to form the electrically conducting nano-element structure having an array of nano-elements and a base physically connecting said array of nano-elements; said material being the nano-element structure material or precursor material from which said array of nano-elements is formed; and
removing said nano-element structure from contact with said template.

2. The process of claim 1 wherein said nano-elements have dimensions in a range of about 50 to 5500 nm in spacing, 10 to 5000 nm in height, and 10 to 5000 nm in their largest lateral dimension.

3. The process of claim 1 wherein said template is created by nano-imprinting into an imprint material and said contacting occurs with disposing of said material into this template; and said nano-element structure so produced is subsequently positioned with its base on a final substrate.

4. The process of claim 3 further comprising disposing a conductive material, an adherence material, or both on said base before said nano-element structure positioning on said final substrate.

5. The process of claim 3 wherein said nano-imprinting is by a roller carrying the pattern for producing said template pattern.

6. The process of claim 3 wherein said nano-imprinting is by a stamp carrying the pattern for producing said template pattern.

7. The process of claim 1 further comprising curing said material with heating or radiation, as needed, to attain electrical or optical properties suitable for the nano-element structure application.

8. The process of claim 1 further comprising disposing at least one of a dopant layer, a conducting material, an optical spacer, a transport control layer, an absorber layer, a counter electrode, or all such layers, to form a photovoltaic device.

9. The process of claim 1 further comprising disposing a dopant layer, an optical spacer, a transport control layer, an absorber layer, a counter electrode, or all such layers, to form an operating device, and then forming a lensing system positioned with respect to the nano-elements to direct light into a conformal covering of each nano-element.

10. The process of claim 1 wherein said material is the nano-element and base material.

11. The process of claim 1 wherein said template is imprinted into the nano-element material or its precursor with said material or its precursor positioned on the final substrate.

12. The process of claim 11 wherein said template is a reused to form further nano-element structures.

13. The process of claim 11 wherein said nano-elements have dimensions in a range of about 50 to 5500 nm in spacing, 10 to 5000 nm in height, and 10 to 5000 nm in their largest lateral dimension

14. The process of claim 11 further comprising curing said material with heating or radiation, as needed, to attain electrical or optical properties suitable for the nano-element structure application.

15. The process of claim 1 further comprising disposing at least one of a dopant layer, a conducting material, an optical spacer, a transport control layer, an absorber layer, a counter electrode, or all such layers, to form a photovoltaic device.

16. The process of claim 1 further comprising disposing a dopant layer, an optical spacer, a transport control layer, an absorber layer, a counter electrode, or all such layers, to form an operating device, and then forming a lensing system positioned with respect to the nano-elements to direct light into a conformal covering of each nano-element.

17. The process of claim 1 wherein said template is defined in a template substrate and the nano-element material or its precursor is printed into this array template forming the nano-element structure, said nano-element structure so produced being subsequently positioned on a final substrate.

18. The process of claim 17 wherein said template is a reused to form further nano-element structures.

19. The process of claim 17 further comprising curing said material with heating or radiation to attain electrical or optical properties suitable for the nano-element structure application,

20. The process of claim 1 further comprising disposing at least one of a dopant layer, a conducting material, an optical spacer, a transport control layer, an absorber layer, a counter electrode, or all such layers, to form a photovoltaic device

21. The process of claim 1 further comprising disposing a dopant layer, an optical spacer, a transport control layer, an absorber layer, a counter electrode, or all such layers, to form an operating device, and then forming a lensing system positioned with respect to the nano-elements to direct light into a conformal covering of each nano-element.

22. (canceled)
